(19) United States
(12) Patent Application Publication
(10) Pub. No.: US 2026/0293597 A1
(43) Pub. Date: Sep. 24, 2026

(54) FOUP POSITIONAL CALIBRATION DEVICE

(71) Applicant: Nanoverse Technologies Ltd, Beaverton, OR (US)

(72) Inventors: William Robertson, Beaverton, OR (US); Jeff Albelo, Beaverton, OR (US)

(73) Assignee: Nanoverse Technologies Ltd, Beaverton, OR (US)

(21) Appl. No.: 19/088,604

(22) Filed: Mar. 24, 2025

(51) Int. Cl. H01L 21/68; B25J 9/16; B25J 11/00; H01L 21/67; H01L 21/677

(52) U.S. Cl. CPC H10P 72/53; B25J 9/1697; B25J 11/0095; H10P 72/0608; H10P 72/3402; H10P 72/3406

(57) ABSTRACT

A semiconductor fabrication facility has numerous Si wafer processing modules. Robotic arms transfer the Si wafers to the processing equipment in these modules, retrieving them from their stacked array in a front opening unified pod (FOUP) with their end effectors. The FOUP resides in a load port in an equipment front end module (EFEM). Precision in retrieving the Si wafers is the key to a higher production yield and to minimizing Si wafer culls. The robots can only move about the module based on the module control computer's instructions based on its 3-D mapping of the EFEM, the load port and the FOUP. Often the mapping's 3-D cartesian coordinates are off slightly such that the directional instructions to the robotic arm are slightly off. This system uses dual lidar sensors mounted on a robotic arm in concert with 3-D reference targets on the EFEM and a FOUP alignment tool to calibrate the robot's three-dimensional awareness of both its spatial relation to the fixed elements of the EFEM as well as to Si wafers in a FOUP.

### COPYRIGHT STATEMENT

A portion of the disclosure of this patent document contains material that is subject to copyright protection. The copyright owner has no objection to the facsimile reproduction by anyone of the patent document or the patent disclosure as it appears in the Patent and Trademark Office patent file or records, but otherwise reserves all copyright rights whatsoever.

### FIELD

The present disclosure relates, in general, to semiconductor processing, and more particularly to the three-dimensional position calibration of a Si wafer retrieval robotic arm at a load port in a semiconductor processing facility.

### BACKGROUND

The transformation of a Si disk (wafer) to a set of semiconductor chips occurs in a semiconductor processing facility through the progression of the Si wafer through a series of wafer processing modules. The microchips produced are extremely small and the throughput of the facility depends on the precision with which the Si wafers are processed. Since this is all done robotically, it is the precision at which the robotic arms operate that dictates the efficiency of the processing facility.

There are several factors which dictate the precision at which the robotic arms function. The modules, complete with the robotic arms, are fabricated at one facility and transported, ready for use, at the end user's facility. They can encounter dimensional damage along the way. The wafers can encounter dimensional or loading problems. The robotic track may not run true to parallel with the linear axis of the module. The robotic arms may experience physical collisions during operation, or the factory loaded robotic arm positioning may just not be that accurate.

Henceforth, a system of determining the precise three dimensional position of a robotic arm within a processing module with respect to the fixed elements of the module and its related equipment, and using this spatial data to overwrite and recalibrate the existing robotic arm positioning application in that module's control computer would greatly enhance the robot's three-dimensional awareness of both its spatial relation to the fixed elements of the module as well as to SI wafers introduced through a load port. This would increase the throughput of the workflow process in the semiconductor processing industry. This invention utilizes and combines known and new technologies in a unique and novel configuration to overcome the aforementioned problems and accomplish this.

### BRIEF SUMMARY

In accordance with various embodiments, an apparatus and method using two different resolution LiDAR sensors to precisely determine the three-dimensional position of a robotic arm within a semiconductor processing facility's EFEM (equipment front end module) or other process module (hereinafter “module”) is provided.

In one aspect, a portable calibration target affixable at different locations about the interior walls of a module that allows a LiDAR sensor to accurately generate a point cloud of three-dimensional Cartesian coordinates representing the distances between the robotic arm and the interior surfaces of the module. This data can then be reconciled algorithmically by the module application, to overwrite and corrected any dimensional discrepancies between the factory mapping and the EFEM's true dimensions.

In another aspect, a FOUP positional calibration tool that works in conjunction with the LiDAR sensor to provide three-dimensional point cloud data to the module control computer to enable the precise calibration of the positioning of the end effectors of the robotic arm within a FOUP. This is also used to overwrite and corrected any dimensional discrepancies between the factory mapping and the FOUP's true dimensions.

In another aspect, an apparatus and method for the calibration of an EFEM dimensional mapping based on LiDAR sensor scan results (point cloud cartesian coordinates) to correct and overwrite the factory robotic arm mapping that uses in part, known SEMI standard dimensions, that requires minimal calibration knowledge or experience of a technician.

In another aspect, correction of a factory EFEM dimensional mapping by a calibration application that is constantly updated for Si wafer location in a FOUP, and for EFEM dimensions based on real time LiDAR position sensing from two LiDAR sensors mounted on the robotic arm that use precisely vertically positioned calibration targets as the reference frame.

Various modifications and additions can be made to the embodiments discussed without departing from the scope of the invention. For example, while the embodiments described above refer to features, the scope of this invention also includes embodiments having different combination of features and embodiments that do not include all the above-described features.

### BRIEF DESCRIPTION OF THE DRAWINGS

A further understanding of the nature and advantages of embodiments may be realized by reference to the remaining portions of the specification and the drawings, in which like reference numerals are used to refer to similar components.

FIG. 1 is a front perspective view of a prior art semiconductor fabrication module grouping;

FIG. 2 is a representative top view of the interior of a prior art EFEM;

FIG. 3 is front view of a FOUP loaded with Si wafers;

FIG. 4 is a perspective view of a lidar target;

FIG. 5 is a top view of robotic arm in an EFEM;

FIG. 6 is a top view of the calibration target placement within an EFEM;

FIG. 7 is a top view of a robotic arm with end effectors facing a FOUP;

FIG. 8 is a side view of a robotic arm with end effectors facing the center of a FOUP;

FIG. 9 is a side view of a robotic arm with end effectors facing the top of a FOUP;

FIG. 10 is a top view of a robotic arm showing the LiDAR scanning patterns,

FIG. 11 is a front view of the solid-state sensor used in the FOUP positional calibration tool;

FIG. 12 is a top cross-sectional view of an end effector taken between the side shelf supports as the entering the positional calibration tool; and

FIG. 13 is a flow chart illustrating the method of calibrating the robot for movement about the EFEM module and its end effector movement into the FOUP.

### DETAILED DESCRIPTION

Reference will now be made in detail to embodiments of the inventive concept, examples of which are illustrated in the accompanying drawings. The accompanying drawings are not necessarily drawn to scale. The described examples are provided for illustrative purposes and are not intended to limit the scope of the invention.

It will be understood that, although the terms first, second, etc. may be used herein to describe various elements, these elements should not be limited by these terms. These terms are only used to distinguish one element from another. For example, a first attachment could be termed a second attachment, and, similarly, a second attachment could be termed a first attachment, without departing from the scope of the inventive concept.

It will be understood that when an element or layer is referred to as being “on,” “coupled to,” or “connected to” another element or layer, it can be directly on, directly coupled to or directly connected to the other element, or intervening elements or layers may be present. In contrast, when an element is referred to as being “directly on,” “directly coupled to,” or “directly connected to” another element, there are no intervening elements present.

As used in the description of the inventive concept and the appended claims, the singular forms “a,” “an,” and “the” are intended to include the plural forms as well, unless the context clearly indicates otherwise. It will also be understood that the term “and/or” as used herein refers to and encompasses all possible combinations of one or more of the associated listed items.

As used herein, the term “EFEM calibration application” refers to a software program developed for operation on the operating platform of the module control computer, that reconciles/corrects the factory preset or current three-dimensional cartesian coordinate mapping (digital representation) of the interior of the EFEM using the three-dimensional point cloud of the interior of the EFEM (real time adjustments) as provided by the LiDAR sensors. The software takes the depth and spatial relationships provided by the point cloud and generates a three-dimensional mesh (mapping) consisting of a network of interconnected vertices, edges, and faces that define the EFEM's interior environment. Much of the original factory preset mapping is established using a sensor determined three-dimensional set of cartesian coordinates for a reference location (who's vertical and horizontal location on the EFEM wall is precisely measured and input to the application) and integrating this with the SEMI standards dimensional data for the EFEM.

As used herein, the term module control computer's “robotic arm positioning application” refers to a software program developed for operation on the operating platform of the module control computer, that provides instructions to the actuators of the robotic arm to drive the arm's joints to follow specific sequences of movements through a combination of pre-defined paths that are based on the three-dimensional cartesian coordinate mapping provided by the EFEM calibration program which provides the robotic arm's spatial awareness. The EFEM calibration application and the robotic positioning program may be integrated into a single application or may be broken out into smaller applications/modules.

As used herein the term “computer” refers to any form of electronic device for receiving, storing, processing, and sharing data, typically in binary/digital form, according to instructions given to it in a program or application, variable or not. With this data it can perform prescribed mathematical and logical operations at high speed. The data may be visually displayed or may be sent to another electronic device for the physical performance of a task by electromechanical equipment (such as a robotic device, or sequenced starting/stopping/running of equipment.) These other electronic devices include computers, embedded computers, microcontrollers, microprocessors, programable logic controllers, programmable or non-programmable logic devices or arrays, application specific integrated circuits (ASICs), smart cards, and the like. In its simplest definition, as used herein with reference to the above discussed equipment, a computer is a device that accepts information (in the form of digitalized data) and manipulates it to accomplish some result based on a software algorithm or sequence of instructions on how the data is to be processed to accomplish the result.

As used herein the term “SEMI standard” refers to a set of international standards and specifications that govern all the safety, materials, equipment, facilities, software, hardware, structures and packaging standards, in a semiconductor fabrication facility. It has been established and codified by the Semiconductor Equipment and Materials Initiative. These include the dimensional standards for the processing module's internal dimensions including openings therein.

As used herein, the terms “robotic arm and robot” are used interchangeably and the term “end effector” refers to the end-of-arm tooling that is used to manipulate things (i.e. Si wafers) at the end of the robotic arm.

As used herein, the term “LiDAR sensor” refers to a light detection and ranging electronic device that has a laser emitter that emits pulses of laser light directed at a target area either from a rotating beam or a solid-state multiple beam array. The sensor has a photodetector that senses the light reflected off the target, back toward the sensor and measures the time of flight it took the light beam to travel there and back. Each laser light pulse generates a data point representing the distance to an object at a specific angle, and with millions of pulses per second emitted, the sensor creates a dense “point cloud” that it sends as digital data to a computing device with the software capability to algorithmically process the point cloud into the 3D shape of the environment. Herein the present device, the robotic positioning application in the module control computer receives the LiDAR sensor's data and uses it to develop the 3D environment of the module's walls, openings and obstacles, the Front Opening Unified Pod (FOUP) and the load ports and corelates this to the SEMI standards for that module and the encoder positions for the robot's track travel and movements, so as to get an extremely precise and accurate positioning model that can overwrite the original positioning model and then can use to it process the movement instructions for the various joints and servo motors of the robotic arm/s to effect the desired actions.

As used herein, the term “module computer or module control computer” refers to an operational computer located at the EFEM (or other module) that has a robotic arm positioning application that provides movement instructions to the robot/robotic arm to accomplish production tasks based on the discrete three-dimensional mapping of that EFEM. This three-dimensional mapping is originally generated and provided by the factory that performs a robotic calibration to a known reference point on/in the EFEM module that is then cross referenced with the SEMI standards for that module, by the module control computer's EFEM calibration application to develop a discrete dimensional mapping for that EFEM or module.

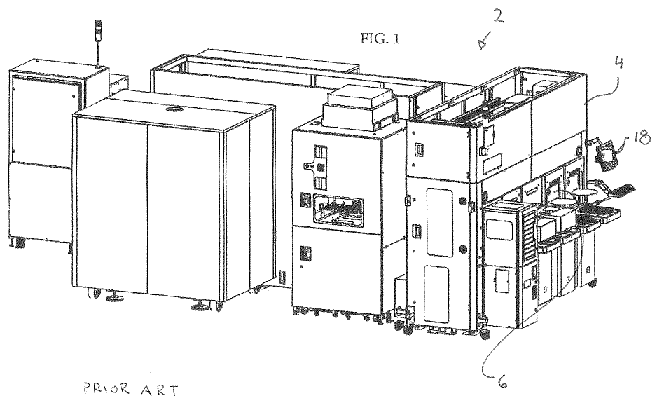

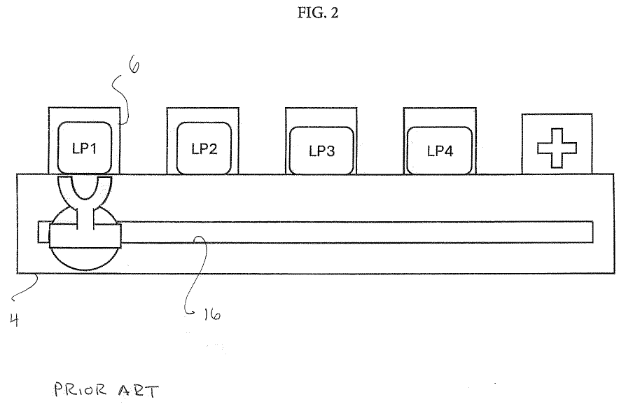

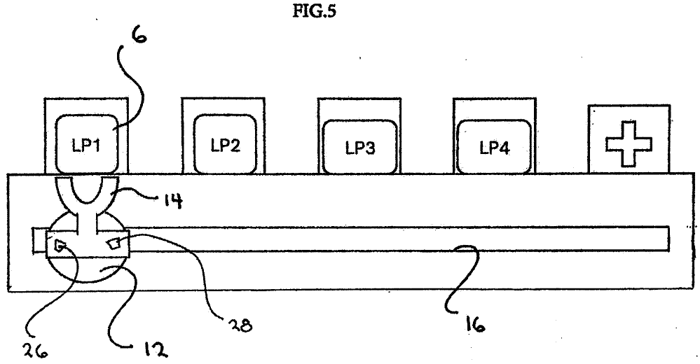

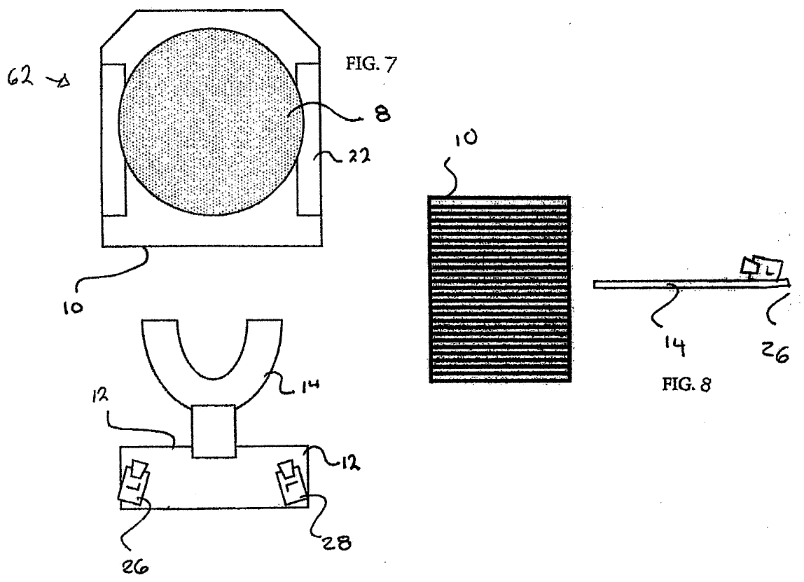

Semiconductor production facilities have a series of semiconductor fabrication and metrology modules, that are stand-alone or integrated into a composite module 2. (FIG. 1) Each module performs one or some of the sequential tasks required to make a Si wafer 8 into a semiconductor device. The Si wafers 8 are transported between modules in boxed vertical arrays of 25 or 14 wafers known as Front Opening Unified Pod (FOUPS) 10 (FIG. 7). These FOUPS 10 are precisely connectable to an equipment front end module (EFEM) 4 that facilitates the transfer of the Si wafers 8 individually through a loading/transfer port 6 (FIG. 5) into the EFEM 4 or composite module 2 the EFEM 4 is attached to. The Si wafers 8 are transferred individually to and from the FOUP 10 in the load port 6 in the EFEM 4 by a robotic arm 12 (FIGS. 5 and 7) having an end effector 14 that appropriately retrieves and precisely places the Si wafer 8 on or off the processing equipment in the module/s 4. The robot 12 may traverse the length of the module 4 along a robotic track 16 reporting its location to the module control computer 18 with track positioning encoders. Theoretically, this track 16 is true and parallel to the length sides of the EFEM 4. The FOUPS 10 are moved between the EFEMs 4 of the various modules by a robotic overhead transfer system.

The semiconductor production facility has a host facility computer that controls the overall semiconductor fabrication process. It directs the operation of the computers that control the FOUP delivery system, the EFEM module control computers 18 (FIG. 1) and each of the other process module computers 18 that in turn, run their module's electro-mechanical tools (including localized module robotic arms 12) through a system of microcomputers, PLC's microcontrollers and microprocessors. The FOUPS 10 are delivered between the EFEMs 4 by an overhead robotic transfer system. The modules are connected to the necessary facility's utilities, including, but not limited to water, electricity, vacuum, fluid drains, HVAC, compressed air and compressed specialty gases (N₂ AR, CO₂ etc.).

The robotic arms 12 precisely perform the work of transforming a Si wafer 8 into an array of semiconductor chip/chipsets within the various processing modules. The precision of their movements in picking up and placing the Si wafers 8 on the various pieces of processing equipment is paramount to the quality of the end product.

The cartesian robotic arms 12 are programmable mechanical arms that are mounted securely to a moveable base residing on a track and have multiple joints that act as axes. The number of joints determine the degrees of freedom of motion that the robotic arm has. The robotic arm positioning application in the module control computer 18 reads programed instructions sent from the module control computer's robotic arm positioning application, and sends them to the actuators in the arm 12 that move the individual joints to the correct angle (position) to allow the stepper/servo motors in the arm 12 to move the arm 12 in exact increments to get the robotic arm's end effector 14 to the desired XYZ Cartesian coordinate location within the EFEM 4. Motion sensors on the arm provide three-dimensional point cloud positional feedback to the robotic arm position application to ensure that the arm moves to position its end effectors at the desired locations and in the desired sequences.

The positioning of the robotic arms 12 in the module 4 is initially dictated by the robotic positioning application in the module control computer 18 and is based on its initial calibration, and from dimensions input to its positioning algorithm from the SEMI standards for that module. Although quite dimensionally accurate and precise, they are within tolerances. Accidents such as collisions between equipment (including robots) do occur within the module as well as problems with the robotic track encoders, and robotic arm position sensors which effect the robot's 12 awareness of its actual three-dimensional position within the module.

Basically, the robotic arm 12 moves around the module 4 shuttling wafers 8 in blind reliance on the initial precision of the positioning instructions in the EFEM module's control computer 18. These positioning instructions are set up at the factory where the process module 4 is fabricated using a programming interface to the factory's system computer. The SEMI standards are input to the system computer (which sets the robotic positioning model) and provides the precise dimensional data of the interior of the module. The factor technician manually operates the robotic arm 12 to perform a few tasks, positioning it in a few reference positions around the module 4. These 3D positions are reported to the system computer via the position sensors in the robotic arm and the robotic track encoders. The software in the system computer algorithmically registers the location data from these sensors to the 3D model provided SEMI standards to locate the robotic arm 12 correctly within the process module 4. However, this does not account for slight out-of-tolerance deviations in the positional dimensions in the module 4 or the parallelism of the robotic track 16 when the module 4 arrives at the semiconductor fabrication facility, for accidents within the module, for non-conforming wafer positioning 20 or for wafer sag 24 in the FOUP.

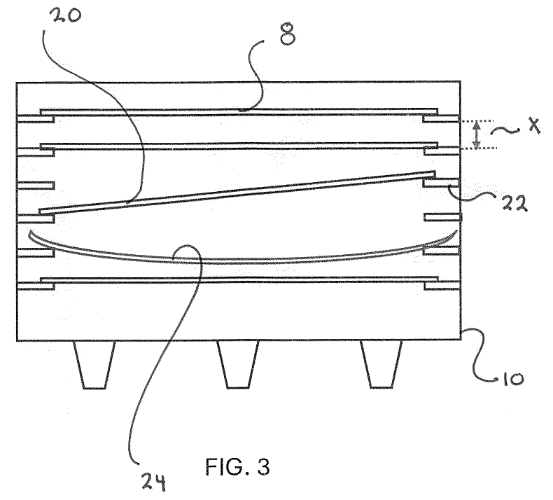

Si wafers 8 (thickness of up to 0.4 mm) are retrieved by the end effectors 14 on the robotic arm 12 which horizontally enters the FOUP 10 in the 10 mm space between the side shelf supports 22 of the FOUP. (Designated dimension X in FIG. 3) It then lifts one of the individual stacked Si wafers 8 up and out of the FOUP 10. Often the Si wafers 8 are cross loaded 20 on two of the FOUP's side shelf supports 22 making retrieval impossible or inviting a collision between the Si wafer 8 and the end effector of the robotic arm 12. Si wafers 8 are prone to a condition known as “wafer sag” where because of the thickness of the wafer or environmental conditions, the wafer sags 24 in its center between its sides where it rests on the FOUP's side shelving array. This condition reduces the normal 10 mm space between adjacently stacked Si wafers which results in an unretrievable Si wafer 8. (See FIG. 3) A typical 300 mm diameter Si wafer sag 24 may be in the 6 mm range. The thickness of a typical semiconductor Si wafer is 0.775 mm. The thickness of the end effectors is 1-5 mm. Thus, there may not enough clearance to navigate a wafer retrieval in all situations based on the dimensional tolerances of the robotic arm. Normally when there is an unretrievable wafer the entire operation is shut down while the FOUP 10 is removed and the Si wafers 8 reloaded. A robotic arm positioning application operating with a more accurate and precise EFEM interior mapping with reduced tolerances could avoid collisions with Si wafers and retrieve other Si wafers in the same FOUP that houses sagging or cross loaded Si wafers.

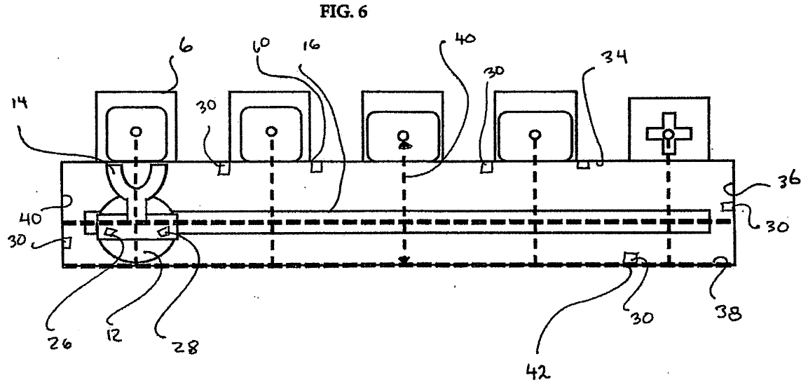

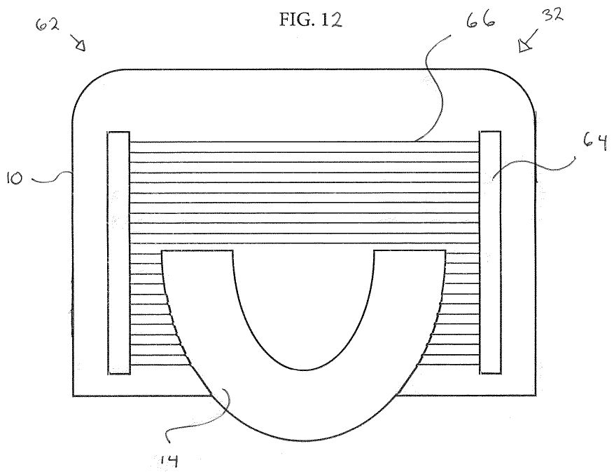

The present invention relates to a novel apparatus and method to provide a precise and accurate three-dimensional point cloud mapping of the dimensions, openings, and equipment location in an EFEM's interior with respect to the robotic arm 12 and/or its end effector 14. The point cloud is developed by using a pair of LiDAR sensors 26 and 28 positioned on the robotic arm 12, a LiDAR dimensional calibration target 30 and a FOUP positional calibration tool 32. The point cloud is algorithmically used by the EFEM calibration application in the module control computer 18 to precisely determine where the robotic arm 12 is in relation to the module's wall surfaces 34, 36, 38 and 40, load ports 6, and other equipment in conjunction with the SEMI standard dimensional data. (FIG. 6) This mapping is algorithmically reconciled with all its inputs and overwrites the original factory mapping to present a current accurate and precise mapping that the module control computer's robotic positioning application can use to shuttle the Si wafers around the EFEM. The point cloud data is also be used to precisely determine the location and condition of the Si wafers 8 in the FOUP 10 to be presented to the robotic positioning application, and in conjunction with a FOUP alignment tool 32, can precisely determine the depth the end 14 effectors traverse into the FOUP 10 to retrieve the Si platters 8. (FIG. 12)

FIG. 1 is a representative top view of an EFEM (processing module). The robotic arm 12 is free to move its end effectors 14 in many degrees of freedom and can also traverse the length of the module 4 along a position encoded track 16. It moves about the module 4 shuttling Si wafers 8 to processing stations or to other connected modules. There are two LiDAR sensors 26 and 28 affixed to the robotic arm 12.

The two LiDAR sensors used are different sensors. The first sensor 26 is a lightweight, small form factor sensor that has 360-degree horizontal scanning. It has a high measurement accuracy and a long range (up to 50 meters). It is suitable for applications requiring full environmental awareness, such as obstacle detection and robotic mapping. Its primary purpose is to map the horizontal distance to the end walls 36 and 40 of the EFEM module 4. (In the preferred embodiment a LightWare® brand LiDAR sensor model LiDar SF45/B is used.) This first sensor 26 provides a horizontal dimensional point cloud of distance to internal vertical wall surfaces using calibration targets 30 set at precise vertical locations on distant end wall surfaces of the module, and at the initial point of reference 30.

The second sensor 28 is another small form factor LiDAR sensor that produces high precision distance measurements but over a short range, generally only a few meters. Its purpose is to provide a point cloud for precise measurement of the distance to the front and rear module walls 34 and 38 and more specifically, the frame-to-load port depth 38 into the FOUP 10, the Si wafers 8 and the load port 6 locations in the module 4 to allow for exact, high precision positioning of the end effector 14. They also use calibration targets 30 set at the edges of the load ports 6, the front and rear walls 34 and 38 (including the initial point of reference 42 used during the initial factory calibration which set the robotic positioning model). It is capable of high-speed measurements as encountered in robotics. (In the preferred embodiment a Baumer® brand LiDAR sensor model M 70-L0070.HH0048.EK is used.)

The point cloud that these sensors 26 and 28 develop is provided to the module control computer 18 as one of the inputs required by the EFEM calibration application's algorithm along with the vertical height of the reference targets, the FOUP alignment tool's positioning data and the SEMI standard dimensional values. These values are reconciled with the factory EFEM mapping to generate a more dimensionally accurate and precise mapping.

Looking at FIGS. 6, 7 and 10 the location of the LiDAR sensors 26 and 28 on the robotic arm 12 can best be seen. In the preferred embodiment the sensors 26 and 28 are positioned on the robot's shoulder and the midline of the sensor's field of view are toed inward toward each other to provide an overlapping scan region 50. (FIG. 10)

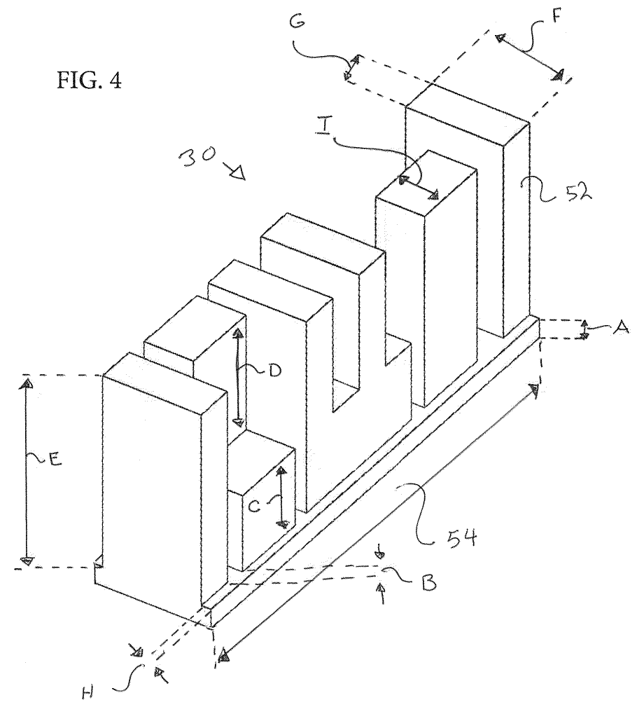

Looking at FIG. 4 it can be seen that a calibration target 30 is a linear three-dimensional array of different shaped cuboids 52 in a spaced configuration. The function is to provide a geometric surface with a plethora of corners, different heights and different widths set apart with gutters at distances sufficient to allow the LiDAR sensors to establish a highly accurate and precise point cloud of the entire calibration target on the wall. The point cloud reflecting the calibration targets can be algorithmically interpreted to allow for the precise determination of distances to the EFEM walls. Scanning a planar EFEM wall does not accurately locate the robot vertically within the module. Knowing the precise distance to the wall along with the precise, measured vertical height of the calibration target 30 and the SEMI standard data with respect to the point cloud for the load port openings, the EFEM internal dimensions in relation to the robotic arm can be precisely mapped by the EFEM calibration application.

In the development of the calibration targets 30, various geometric configurations with multiple corners were used. Targets used with square grids placed close together did not provide the point cloud resolution required for precise distancing. Experimentally, it was determined that different rectangular shapes, spaced properly apart with 10 mm wide gutters, and having differing heights (four counting the wall itself) worked best for the development of a precise point cloud to determine distance to wall measurements.

The target 30 is a low sheen polymer, linear random array of cuboids 52 extending normally from a planar base 54, 210 mm long and 70 mm wide. Some of the cuboids are separated by a gutter B 10 mm wide while other adjacent cuboids abut. The base 54 has a height A of 10 mm and the cuboids 52 sitting on the base 54 have a first height C of 40 mm or second height D that is 60 mm higher. (The second height is a total height E of 100 mm from the top face of the base 54.) The lengths of the cuboids F are 60 mm and the widths G and I are either 25 mm or 40 mm. The cuboids 52 are arranged at a distance H of 5 mm from the edge of the base. Their length axes (x axis) are arranged either perpendicular or parallel to the length axis or the width axis (y axis) of each other individual cuboid. The width and lengths of the cuboids vary from 15 mm to 25 mm.

In use, the calibration targets 30 are secured to the walls of the module 4 at a precisely measured vertical distance from the floor of the module and a horizontal distance from the reference point or form a load port edge as knows via the SEMI standard dimensions. This vertical height is input to the EFEM calibration application to allow the target's point cloud to be algorithmically corelated to the Semi standard dimensions to enable full EFEM dimensional mapping as follows. The robotic arm 12 will be manually moved about the module 4 with both LiDAR sensors 26 and 28 scanning all the interior wall surfaces and the calibration targets 30 affixed in their strategic locations at their accurately and precisely measured vertical heights from the EFEM floor. (These calibration targets 30 are at both end walls 36 and 40, the initial reference point 42 and the edges of the load ports 60). The point clouds established will be used to establish the distance from the robotic arm to all the interior walls of the EFEM, if the robotic track is parallel with the front and back walls (and linear axis of the EFEM) and the precise location of the edges of each of the load ports 6. This point cloud in conjunction with the SEMI standard dimensional data will be algorithmically reconciled by the EFEM calibration application in the module computer 18 to establish the true three-dimensional mapping of the interior dimensions of the EFEM. This mapping will then be used to generate the operational instructions the module control computer's robotic arm positioning application provides to the robot's joints and servo motors to move the end effector to retrieve Si wafers 8 from the FOUP.

The FOUP is precisely fabricated to the dimensions and tolerances of the specifications of the SEMI standard for the FOUP for that load port in that EFEM. With the FOUP side shelf supports 22 locations and their equal spacing between them known from the SEMI standards, the location of the Si wafers 8 is also known and the module control computer can direct the robotic arm and its end effector to retrieve the Si wafers. Problems are encountered when there are cross-fed or sagging wafers in the FOUP. The mapping assumes that the Si wafers are all in their theoretical locations within the FOUP. Since the computer cannot see them, the robotic arm usually crashes into the wafer destroying it and others around it and possibly knocking the robotic arm slightly out of calibration. This situation can be eliminated using the FOUP calibration tool 62 in conjunction with the two LiDAR sensors and using the two Lidar sensors at the time of Si wafer retrieval. The FOUP calibration tool 62 allows for a highly accurate mapping of the FOUP so the end effector can be extremely precisely located in the small spaces between the adjacently stacked Si wafers. The use of the two LiDAR sensors for retrieval will provide an overlapping point cloud to the robotic arm positioning application that will algorithmically recognize the precise location of the Si wafers and any anomalies, and compensate for these in the robotic arm positioning instructions to allow the robotic arm to work around these anomalies to continue retrieving Si wafers from the FOUP

The precise positioning of the end effector 14 within the FOUP 10 in the load port 6 is accomplished with the help of a FOUP positioning tool 62. As illustrated in FIG. 7. There are two LiDAR sensors 26 and 28 mounted atop the robotic arm 12 (preferably on its shoulder). These are toed inward toward each other to present an overlapping scan pattern 50. (FIG. 10) These LiDAR sensors 26 and 28 see the wafers 8 and their horizontal positioning (which is good for identifying cross fed Si wafers or sagging wafers) but do not present a precise set of depth mapping point cloud data to the module computer 18. The side shelf supports have a standardized spacing between them as set forth in the SEMI standards. (Generally, this is 10 mm.)

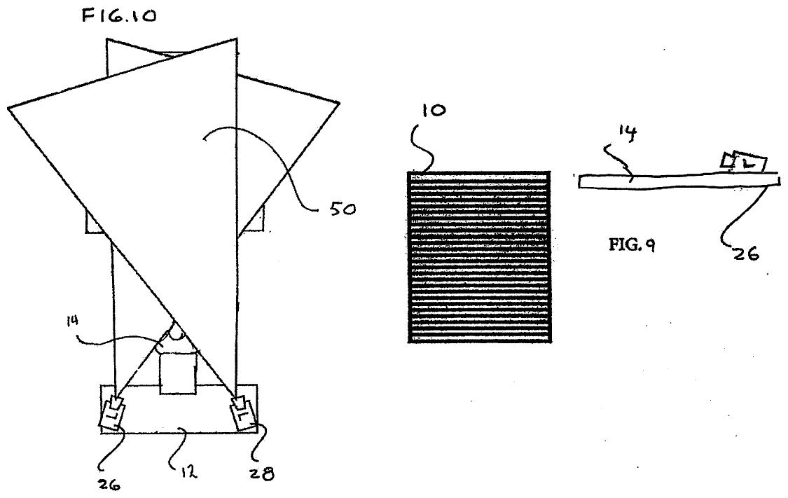

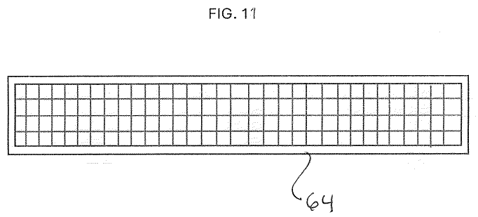

The FOUP calibration tool 62 has a solid-state position sensor 64 mounted horizontally on the side walls of the FOUP where the side shelf supports 22 reside. The position sensor 64 is in data communication with the module control computer 18 either wirelessly or via a hard-wired connection. The FOUP (or similar tape frame loader) is built to exacting dimensions as set forth in the appropriate SEMI standard. They have a series of locating pegs that frictionally fit into recesses in the load port table. This precisely positions the FOUP and its Si wafers 8 in the load port 6 at the vertical and horizontal positions in the EFEM that is specified by the SEMI standards. The motion sensor 64 is made up of a solid-state horizontal array of sensors 64 that project their horizontal and vertical beam matrix between the FOUP sides. The end effector 14 entering the FOUP horizontally, breaks the beam matrix. This broken beam sensor data is provided to the EFEM calibration application in the module control computer 18 which algorithmically determines the depth which the end effectors 14 have entered the FOUP 10 and the vertical position in the FOUP that the end effectors have entered. Since the sensor 64 has a vertical beam component, the end effector 14 can be sent into the FOUP at various heights as shown in FIGS. 8 and 9 to obtain a set of vertical as well as depth readings. This data is algorithmically reconciled in the EFEM calibration application with respect to the FOUP dimensional data provided by the SEMI standards, to create and continually refine an accurate three-dimensional mapping of the FOUP in its current loaded configuration. With this higher degree of precision and accuracy, the end effectors can more precisely be controlled to retrieve Si wafers, even in situations where they are cross-loaded or experiencing extreme wafer sag. The eliminates the need to shut down the production process and pull the FOUP for reloading because of a single bad Si wafer.

These accurate and precise positioning coordinates with the true three-dimensional mapping now in the module control computer 18 allows the generation of robotic arm instructions that will allow the retrieval of Si wafers 8 in a FOUP that have been cross fed or are sagging, without crashing the end effector 14 into a Si wafer that falls outside the acceptable loading dimensional tolerances.

As can be seen the FOUP calibration tool 62 does two things. It can be used in the initial calibration of the EFEM module 4 to set the load port depths and heights of the end effectors, and it can be used in an ongoing function to detect cross slotted wafers and sagging wafers which can then be bypassed for retrieval by the end effectors 14 which, due to the enhanced algorithmic mapping can precisely retrieve the remaining properly loaded Si wafers in the FOUP.

Once the precise location of the FOUP/load port is in the module control computer, the two LiDAR scanners mounted on the robotic arm will accurately be able to present a 3-D data of the contents of the FOUP to the robotic positioning application for algorithmic determination of whether to attempt to retrieve a wafer or not, and if so, what 3-D positioning of the robotic arm would be best to accomplish this.

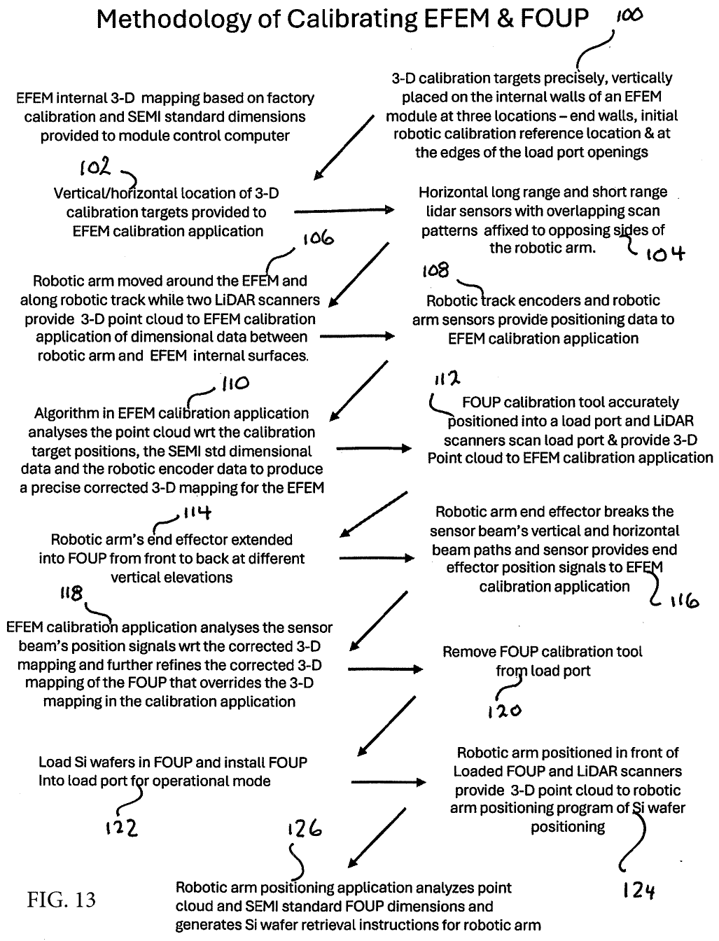

FIG. 13 shows the method steps in calibrating the dimensions of the interior of the EFEM (or other processing module) as well as calibrating the horizontal depth and vertical height the robotic arm's end effectors travel into a FOUP to retrieve a Si wafer. The LiDAR point cloud and FOUP calibration tool's sensor data are reconciled with the SEMI standard dimensional data by an algorithmic positioning application in the module control computer to establish a more precise and accurate three-dimensional mapping of the EFEM interior dimensions.

The steps for the method to establish an accurate three-dimensional mapping of the EFEM, the FOUP, and the Si wafers in the FOUP, that overrides the original factory EFEM calibration and is to be used in the movement instructions from the module control computer to the robotic arm are:
Installing three-dimensional calibration targets on the interior of an EFEM at precise vertical and horizontal interior locations selected from the group consisting of the initial factory robotic calibration reference point, the EFEM end walls, the EFEM front and back walls, and the EFEM front wall adjacent the load port openings (100);
Inputting the three-dimensional vertical and horizontal locations of the calibration targets to the module control computer's EFEM calibration application (102);
Affixing a horizontal, long range first LiDAR sensor to the robotic arm 104);
Affixing a horizontal and vertical, short range second LiDAR sensor to the robotic arm such that a scanning pattern of the first and second LiDAR sensors overlap within the confines of the EFEM, and face forward of the end effector (104);
Moving the robotic arm around the EFEM and along the robotic track while the two LiDAR sensors scan the walls of the EFEM, developing a three-dimensional point cloud of the EFEM from the point of reference of the robotic arm (106);
Providing the three-dimensional point cloud to the module control computer's EFEM calibration application (106);
Providing the robotic track encoder data and the robotic arm position sensors to the process computer's EFEM calibration application (108);
Algorithmically reconciling the point cloud data with the initial factory mapping and the SEMI standard dimensional data to establish a new three-dimensional mapping of the EFEM interior that considers the parallelism of the robotic track, the precise size, location and elevation of the load ports (110);
Installing and locking a FOUP calibration tool at a load port, said FOUP calibration tool having a beam sensor that provides a horizontal and vertical beam matrix across an internal width of a FOUP (112);
Positioning the robotic arm in front of the load port that the FOUP calibration tool is locked into, and scanning the load port to develop a three-dimensional point cloud of the FOUP (112);
Moving the robotic arm's end effectors into the FOUP calibration tool to break the beam matrix, signaling the sensor of the three-dimensional location of the tip of the end effector within the FOUP (114 and 116);
Providing point cloud of the FOUP and the positional data of the end effector within the FOUP, to the module control computer's EFEM calibration application (116);
Algorithmically reconciling the point cloud and positional data mapping of the FOUP and end effector with the current mapping to establish a new three-dimensional mapping of the FOUP (118);
Removing the FOUP calibration tool (120).

The EFEM is now calibrated for robotic arm manipulation to retrieve Si wafers from the FOUP. To use the LiDAR sensors to enable precise retrieval of Si wafers from the FOUP by the robotic arm, (operational mode) the steps are:
Load Si wafers into FOUP and precisely position and lock FOUP into load port (122)
Positioning the robotic arm in front of the load port that the FOUP is locked into, and scanning the load port to develop a three-dimensional point cloud of the Si wafers' precise locations within the FOUP (124);
Providing the point cloud's precise locations of the Si Wafers to the process computer's robotic arm positioning application for algorithmic determination of which Si wafers can be retrieved, and what optimal position the end effector should be moved to, to safely retrieve a Si wafer (124);
Generation of robotic arm instructions to retrieve Si wafers from that FOUP based on the position of the Si wafer in the FOUP and on the condition of the Si wafer (126).

It is well known by one skilled in the art that some of these steps may be performed in a different order yet would accomplish the same result.

While certain features and aspects have been described with respect to exemplary embodiments, one skilled in the art will recognize that numerous modifications are possible. Moreover, while the procedures of the methods and processes for building, assembling and using the devices described herein are described in a particular order for ease of description, unless the context dictates otherwise, various procedures may be reordered, added, and/or omitted in accordance with various embodiments.

Consequently, in view of the wide variety of permutations to the embodiments described herein, this detailed description and accompanying material is intended to be illustrative only and should not be taken as limiting the scope of the inventive concept. What is claimed as the invention, therefore, is all such modifications as may come within the scope and spirit of the following claims and equivalents thereto.

Having thus described the invention, what is claimed as new and desired to be secured by Letters Patent is as follows:

1. A method to calibrate an EFEM module control computer's three-dimensional mapping in an EFEM calibration program of a Front Opening Unified Pod (FOUP) in an EFEM load port in a semiconductor processing facility, comprising the steps of:
loading Si wafers onto into said FOUP, suspended on a set evenly spaced FOUP side shelf supports,
installing and locking a (FOUP) calibration tool into a precise reference position in said load port, said FOUP calibration tool having a FOUP solid-state horizontal array of sensors that provides a horizontal and vertical beam matrix across an internal width of said FOUP such that when said beam matrix is interrupted by an end effector of a robotic arm, said sensor generates a location data of the three-dimensional cartesian coordinate location of where in the FOUP said beam matrix is interrupted;
moving said robotic arm's end effectors into various positions within said FOUP calibration tool to interrupt said beam matrix, so said sensor generates three-dimensional location data of the position of said end effector within said FOUP;
providing said three-dimensional location data of said position of said end effector within said FOUP, from said FOUP sensor to said EFEM calibration program in said module control computer; and
establishing a new three-dimensional mapping of said end effector's position in said FOUP by algorithmically reconciling said dimensional data with the previous factory mapping of said EFEM interior with respect to said robotic arm.

2. The method to calibrate the three-dimensional mapping of a Front Opening Unified Pod (FOUP) of claim 1, comprising the additional steps of:
affixing a horizontal, long range first LiDAR sensor to an EFEM's robotic arm;
affixing a horizontal and vertical, short range second LiDAR sensor to said robotic arm such that a scanning pattern of said first and said second LiDAR sensors overlap within the confines of said EFEM, and face toward an end effector of said robotic arm;
scanning said FOUP calibration tool and said load port with said first and said second LiDAR sensors to develop a point cloud while performing the step of moving said robotic arm's end effectors into various positions within said FOUP calibration tool to interrupt said beam matrix;
providing said point cloud from said LiDAR sensors to said EFEM calibration program in said module control computer; and
establishing a new three-dimensional mapping of said end effector's position in said FOUP by algorithmically reconciling said point cloud and said dimensional data with an initial factory mapping of said EFEM interior with respect to said robotic arm.

3. The method to calibrate the three-dimensional mapping of a Front Opening Unified Pod (FOUP) of claim 1, comprising the additional last step of:
providing said new three-dimensional mapping to a robotic arm positioning program in said EFEM control computer to enable the generation of accurate and precise three-dimensional position instructions to said robotic arm.

4. The method to calibrate the three-dimensional mapping of a Front Opening Unified Pod (FOUP) of claim 3, comprising the additional last step of:
providing said new three-dimensional mapping to a robotic arm positioning program in said EFEM control computer to enable the generation of accurate and precise three-dimensional position instructions to said robotic arm.

5. A calibration tool connectable to an EFEM control computer, for calibrating a three-dimensional mapping of a Front Opening Unified Pod (FOUP) when installed into a load port of an Equipment Front End Module (EFEM) comprising:
a FOUP built to the dimensions and tolerances specified by a SEMI standard for that EFEM to precisely lock into a load port for that EFEM;
a solid-state horizontal array of sensors placed between side shelf supports of said FOUP, said sensors connected to an EFEM control computer,
a horizontal and vertical beam matrix projected across an internal width of said FOUP, generated by said solid state horizontal array of sensors;
a location data of the three-dimensional cartesian coordinates of an end effector of a robotic arm generated by said solid state horizontal array of sensors in said FOUP when said beam matrix is interrupted by said end effector of a robotic arm traversing into said FOUP, said location data transmittable to said EFEM control computer for three-dimensional mapping of said FOUP.

6. The calibration tool connectable to an EFEM control computer of claim 3, further comprising:
a horizontal, long range first LiDAR sensor affixed to an EFEM's robotic arm and connected to said EFEM control computer;
a horizontal and vertical, short range second LiDAR sensor affixed to said EFEM's robotic arm and connected to said EFEM control computer;
a scanning pattern of said first and said second LiDAR sensors that overlaps within the confines of said EFEM, said scanning pattern facing toward an end effector of said robotic arm;
a three-dimensional cartesian coordinate point cloud of said scanning pattern produced by said first and second LiDAR sensors and transmittable to said EFEM control computer for three-dimensional mapping of said FOUP.
